(19) United States
(12) Patent Application Publication
(10) Pub. No.: US 2014/0224294 A1
(43) Pub. Date: Aug. 14, 2014

(54) THERMOELECTRIC CONVERSION ELEMENT AND METHOD OF MANUFACTURING THE SAME

(71) Applicants: Shigeru Koumoto, Tokyo (JP); Akihiro Kirihara, Tokyo (JP); Masahiko Ishida, Tokyo (JP)

(72) Inventors: Shigeru Koumoto, Tokyo (JP); Akihiro Kirihara, Tokyo (JP); Masahiko Ishida, Tokyo (JP)

(73) Assignee: NEC CORPORATION, Tokyo (JP)

(21) Appl. No.: 14/347,126

(22) PCT Filed: Sep. 15, 2012
(86) PCT No.: PCT/JP2012/073754

§ 371 Date: Mar. 25, 2014

(30) Foreign Application Priority Data
Sep. 27, 2011 (JP) 2011-210545
Feb. 29, 2012 (JP) 2012-044148

(51) Int. Cl. H01L 37/00

(52) U.S. Cl. CPC H01L 37/00
USPC 136/205; 438/3; 136/201

(57) ABSTRACT

A thermoelectric conversion element of the present invention includes: a magnetic layer; and an electrode layer formed on the magnetic layer. The electrode layer includes: a first region, and a second region having lower spin current—electric current conversion efficiency and resistivity than those of the first region.

### TECHNICAL FIELD

The present invention relates to a thermoelectric conversion element that uses the spin-Seebeck effect and the inverse spin-Hall effect and a method of manufacturing the same.

### BACKGROUND ART

In recent years, a lot of attention has been paid to an electronic technique referred to as “spintronics. The electronics uses only the “charge” which is one characteristic of electrons. However, in addition to this, the spintronics positively use the “spin” which is another characteristic of the electrons. In particular, a “spin current” which is a current of spin angular momentum of the electrons is an important concept. Since energy dissipation of the spin current is small, there is a possibility that information transmission with high efficiency can be attained by using the spin current. Thus, generation, detection and control of the spin current are the important theme.

For example, a phenomenon is known that the spin current is generated when an electric current flows. This is referred to as the “spin-Hall effect”. Also, its inverse phenomenon is known that electromotive force is generated when the spin current flows. This is referred to as the “inverse spin-Hall effect”. The spin current can be detected by using the inverse spin-Hall effect. Incidentally, the spin-Hall effect and the inverse spin-Hall effect are significantly developed in a substance (e.g. Pt, Au) in which the spin orbit coupling” is great.

Also, the existence of the “spin-Seebeck effect” in a magnetic substance is, made clear by the recent research. The spin-Seebeck effect is a phenomenon that, when a temperature gradient is applied to the magnetic substance, the spin current is induced in a direction parallel to the temperature gradient (e.g. refer to a patent literature 1, a non-patent literature 1 and a non-patent literature 2). That is, with the spin-Seebeck effect, heat is converted into the spin current (thermal spin current conversion). The patent literature 1 reports the spin-Seebeck effect in a Ni Fe film that is ferromagnetic metal. The non-patent literatures 1 and 2 report the spin-Seebeck effect on an interface between a metal film and a magnetic insulator such as yttrium iron garnet (YIG, Y₃Fe₅O₁₂).

Incidentally, the spin current induced by the temperature gradient can be converted into an electric field (a current or a voltage) by using the above inverse spin-Hall effect. In short, by jointly using the spin-Seebeck effect and the inverse spin Hall effect, it is possible to attain “thermoelectric conversion” in which the temperature gradient is converted into electricity.

FIG. 1 shows a configuration of a thermoelectric conversion element disclosed in the patent literature 1. A thermal spin current converter 102 is formed on a sapphire substrate 101. The thermal spin current converter 102 includes a lamination structure composed of a Ta film 103, a PdFtMn film 104 and a NiFe film 105. The NiFe film 105 has magnetization in an in-plane direction. Moreover, Pt electrode 106 is formed on the NiFe film 105. Then, both ends of the Pt electrode 106 are connected to terminals 107-1 and 107-2, respectively.

In the thermoelectric conversion element as configured above, the NiFe film 105 acts a role of generating the spin current from the temperature gradient by the spin-Seebeck effect, and the Pt electrode 106 acts a role of generating the electromotive force from the spin current by the inverse spin-Hall effect. Specifically, when the temperature gradient is applied in the in-plane direction of the NiFe film 105, the spin current is generated in a direction parallel to the temperature gradient by the spin-Seebeck effect. Then, the spin current flows from the NiFe film 105 into the Pt electrode 106, or, the spin current flows from the Pt electrode 106 into the NiFe film 105. In the Pt electrode 106, by the inverse spin-Hall effect, an electromotive force is generated in a direction orthogonal a spin current direction and a NiFe magnetization direction. The electromotive force can be taken out from the terminals 107-1 and 107-2 placed at both ends of the Pt electrode 106.

As the other related art, a patent literature 2 discloses an electrode material that is used for a thermoelectric conversion element which uses a thermoelectric semiconductor. The electrode material includes: a core material made of low-thermal expansion metal material; and a low resistance metal material layer that is cladded on a surface of the core material.

### CITATION LIST

### Patent Literature

[PTL 1] JP 2009-130070A

[PTL 2] JP 2004-63585A

### Non Patent Literature

[NPL 1] Uchida et al., “Spin Seebeck insulator”, Nature Materials, 2010, vol. 9, p. 894

[NFL 2] Uchida et al., “Observation of longitudinal spin-Seebeck effect in magnetic insulators”, Applied Physics Letters, 2010, vol. 97, P172505.

### SUMMARY OF INVENTION

the Pt electrode 106 of the thermoelectric conversion element shown in FIG. 1, the electromotive force is generated from the spin current by the inverse spin-Hall effect. However, a part of a current driven by the electromotive force is converted into a spin current by the spin Hall effect which is the inversion process. That is to say, the part of the electric current generated from the spin current by the inverse spin-Hall effect is lost by inversion process. This causes a decrease of the thermoelectric conversion efficiency.

An object of the present invention is to provide a technique which can suppress, in the thermoelectric conversion element which uses the inverse spin-Hall effect, the decrease of the thermoelectric conversion efficiency by the spin-Hall effect which is the inversion process.

In an aspect of the present invention, a thermoelectric conversion element is provided. The thermoelectric conversion element includes: a magnetic layer; and an electrode layer formed on the magnetic layer. The electrode layer includes: a first region, and a second region having lower spin current—electric current conversion efficiency and resistivity than those of the first region.

According to the present invention, in the thermoelectric conversion element which uses the inverse spin-Hall effect, the decrease of the thermoelectric conversion efficiency by the spin-Hall effect which is the inversion process can be suppressed.

### BRIEF DESCRIPTION OF DRAWINGS

The above and other objects, advantages and features of the present invention will be more apparent from the following description of certain exemplary embodiments taken in conjunction with the accompanying drawings.

FIG. 1 is a perspective view schematically showing a thermoelectric conversion element described in the patent literature 1;

FIG. 2 is a perspective view schematically showing a configuration of a thermoelectric conversion element according to a first exemplary embodiment of the present invention;

FIG. 3 is a conceptual view showing properties of a conversion electrode and a conduction electrode of the thermoelectric conversion element according to the first exemplary embodiment of the present invention;

FIG. 4 is a schematic view showing another configuration of the thermoelectric conversion element according to the first exemplary embodiment of the present invention;

FIG. 5 is a perspective view schematically showing a configuration of the thermoelectric conversion element according to a second exemplary embodiment of the present invention;

FIG. 6 is a conceptual view showing properties of a conversion electrode and a conduction electrode of the thermoelectric conversion element according to the second exemplary embodiment of the present invention;

FIG. 7A is a schematic view showing a configuration example of an external connection terminal of the thermoelectric conversion element according to the second exemplary embodiment of the present invention;

FIG. 7B is a schematic view showing another configuration example of the external connection terminal of the thermoelectric conversion element according to the second exemplary embodiment of the present invention;

FIG. 7C is a schematic view shoving still another configuration example of the external connection terminal of the thermoelectric conversion element according to the second exemplary embodiment of the present invention;

FIG. 8 is a schematic view showing another configuration of the thermoelectric conversion element according to the second exemplary embodiment of the present invention;

FIG. 9 is a schematic view showing a configuration of the thermoelectric conversion element according to a third exemplary embodiment of the present invention;

FIG. 10 is a schematic view showing another configuration of the thermoelectric conversion element according to the third exemplary embodiment of the present invention;

FIG. 11 is a perspective view schematically showing a configuration of the thermoelectric conversion element according to a fourth exemplary embodiment of the present invention;

FIG. 12 is a schematic view showing a configuration example of the thermoelectric conversion element according to the fourth exemplary embodiment of the present invention;

FIG. 13 is a schematic view showing another configuration example of the thermoelectric conversion element according to the fourth exemplary embodiment of the present invention;

FIG. 14 is a schematic view showing still another configuration example of the thermoelectric conversion element according to the fourth exemplary embodiment of the present invention;

FIG. 15 is a perspective view schematically showing a configuration of the thermoelectric conversion element according to a fifth exemplary embodiment of the present invention; and

FIG. 16 is a conceptual view summarily showing the configuration of the thermoelectric conversion element according to the exemplary embodiments of the present invention.

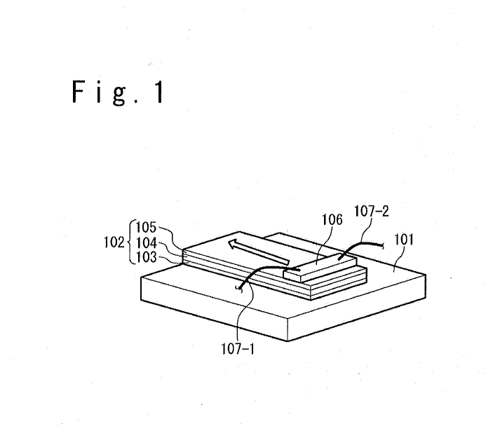

### DESCRIPTION OF EXEMPLARY EMBODIMENTS

The thermoelectric conversion element according to the exemplary embodiment of the present invention will be described below with reference to the attached drawings.

### 1. First Exemplary Embodiment

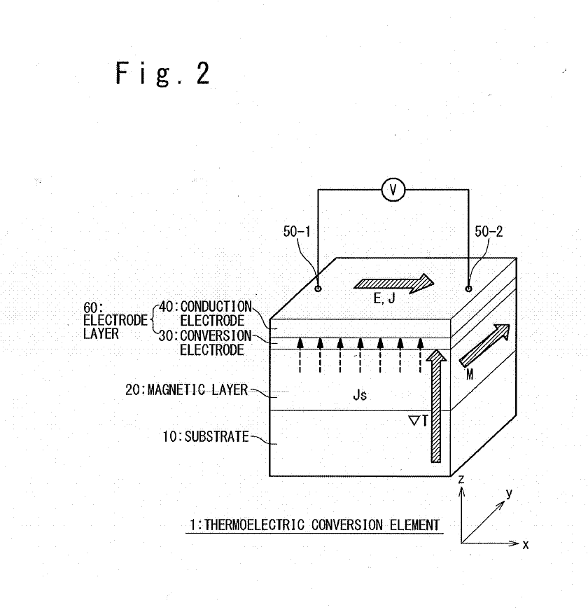

FIG. 2 is a configuration of a thermoelectric conversion element 1 according to the first exemplary embodiment. The thermoelectric conversion element 1 includes a substrate 10, a magnetic layer 20, an electrode layer 60 and a pair of external connection terminals 50 (50-1 and 50-2). The magnetic layer 20 is formed on the substrate 10, and the electrode layer 60 is formed on the magnetic layer 20. In short, the substrate 10, the magnetic layer 20 and the electrode layer 60 are laminated in this order. This lamination direction is hereinafter referred to as a z direction. The in-plane directions orthogonal to the z direction are an x direction and a y direction. The x direction and the y direction are orthogonal to each other.

The magnetic layer 20 is a heat-spin current converter for developing the spin-Seebeck effect. In short, the magnetic layer 20 generates (drives) a spin current Js from a temperature gradient ∇T by the spin-Seebeck effect. A direction of the spin current Js is parallel or anti-parallel to a direction of the temperature gradient ∇T. In the example shown in FIG. 2, the temperature gradient ∇T of a +z direction is applied, and the spin current Js along the +z direction or −z direction is generated.

Material of the magnetic layer 20 may be ferromagnetic metal or magnetic insulating material. As the ferromagnetic metal, NiFe, CoFe, CoFeB and the like may be listed. As the magnetic insulating material, yttrium iron garnet (YIG, Y₃Fe₅O₁₂), YIG (Bi:YIG) in which bismuth (Bi) is doped, YIG (LaY₂Fe₅O₁₂) in which lantern (La) is added, yttrium gallium iron garnet (Y₃Fe₅₋ₓGaₓO₁₂) and the like may be listed. Incidentally, from the standpoint of suppressing heat conduction caused by electrons, it is preferable to use the magnetic insulating material.

The electrode layer 60 includes a conversion electrode 30 (a first electrode film) and a conduction electrode 40 (a second electrode film). In the present exemplary embodiment, the conversion electrode 30 and the conduction electrode 40 are distributed in the z direction. In detail, the conversion electrode 30 is formed on the magnetic layer 20, and the conduction electrode 40 is formed on the conversion electrode 30. In short, the conversion electrode 30 is positioned between the magnetic layer 20 and the conduction electrode 40, in the z direction.

The conversion electrode 30 is the spin current—electric current converter for developing the inverse spin-Hall effect (the spin orbit interaction). In short, the conversion electrode 30 generates the electromotive force from the spin current Js by the inverse spin-Hall effect. Here, a direction of the generated electromotive force is given by the exterior product of a direction of magnetization M of the magnetic layer 20 and a direction of the temperature gradient ∇T (E//M×∇T). In the present exemplary embodiment, in order to efficiently generate electric power, the element is configured such that the direction of the electromotive force becomes the in-plane direction of the conversion electrode 30. For example, as shown in FIG. 2, the direction of the magnetization M of the magnetic layer 20 is the +y direction, the direction of the temperature gradient ∇T is the +z direction, and the direction of the electromotive force is the +x direction.

Material of the conversion electrode 30 includes metal material in which the “spin orbit coupling” is great. For example, the metal material such as Au, Pt, Pd, Ir or other metal material which has an f-orbit in each of which the spin orbit coupling is relatively great, or alloy material which includes any of them. Also, the similar effect can be obtained only by an operation in which the material such as Au, Pt, Pd, Ir or the like is doped at about 0.5 to 10 weight % into typical material such as Cu and so on.

Incidentally, from the standpoint of efficiency, it is preferable that the film thickness of the conversion electrode 30 is set to an approximate “spin diffusion length (spin relaxation length)” which depends on the material. For example, when the conversion electrode 30 is the Pt film, its film thickness is desired to be set to about 10 to 30 nm.

The conduction electrode 40 is formed on the conversion electrode 30 in contact with the conversion electrode 30. Moreover, two external connection terminals 50-1 and 50-2 are formed in contact with the conduction electrode 40 and separated from each other in the x direction. When the electromotive force is generated, potentials of the external connection terminals 50-1 and 50-2 differ from each other. By using those external connection terminals 50-1 and 50-2, it is possible to extract an electric current (electric power) generated in the conversion electrode 30.

Incidentally, the material of the conversion electrode 30 and the material of the conduction electrode 40 are not limited to the metal material and the alloy material. The conversion electrode 30 may be oxide such as ITO and so on. Also, the conduction electrode 40 may be carbon-based material such as graphene and so on.

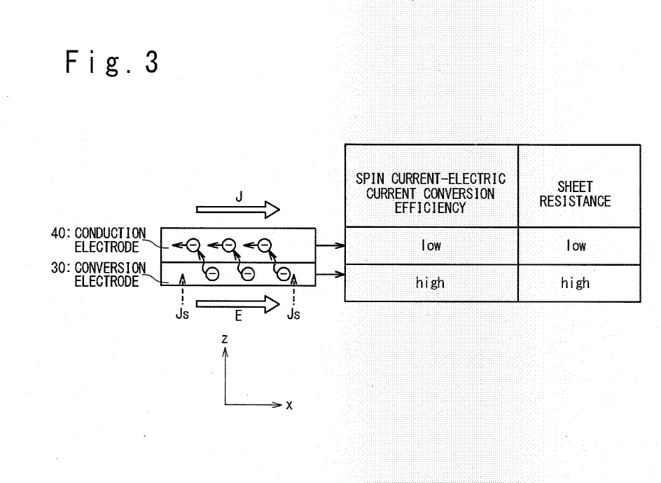

FIG. 3 shows properties of the conversion electrode 30 and the conduction electrode 40 according to the present exemplary embodiment. As the properties, “sheet resistance” and “spin current—electric current conversion efficiency” are considered. The spin current—electric current conversion efficiency is conversion efficiency between the spin current and the electric current, which is caused by the spin orbit coupling (the spin-Hall effect and the inverse spin-Hall effect). The spin current—electric current conversion efficiency can be approximately considered as a so-called “spin-Hall angle”. Incidentally, a measuring method of the spin current—electric current conversion efficiency is, for example, described in the following literature: Niimi et al., “Extrinsic Spin-Hall Effect Induced by Iridium Impurities in Copper”, Physical Review Letters, 106, 126601, 2011.

According to the present exemplary embodiment, the sheet resistance of the conduction electrode 40 is lower than the sheet resistance of the conversion electrode 30. Also, the spin current—electric current conversion efficiency of the conduction electrode 40 is lower than the spin current—electric current conversion efficiency of the conversion electrode 30. That is, in the conduction electrode 40 as compared with the conversion electrode 30, the electric current flows easily and the spin current—electric current conversion is difficult to occur.

In the conversion electrode 30, the inverse spin-Hall effect is greatly developed, and the spin current Js is converted into the electric current with high efficiency. Most of the electric current generated in the conversion electrode 30 is transmitted to the conduction electrode whose sheet resistance is lower than that of the conversion electrode 30. In the conduction electrode 40, the spin-Hall effect is not almost developed, and most of the electric current is not converted into the spin current. That is, a part of the electric current, which is converted from the spin current Js by the inverse spin-Hall effect, is, almost prevented from being returned to the spin current by the spin-Hall effect. Thus, the loss of the electric current in the electrode layer 60 is greatly reduced. This fact indicates the improvement of the thermoelectric conversion efficiency.

The combination of the material of the conversion electrode 30 and the material of the conduction electrode 40 is variously considered. For example, the material of the conversion electrode 30 is Pt (resistivity=104 nΩ.m) and the material of the conduction electrode 40 is Cu (resistivity=17 nΩ.m). In this case, the conversion electrode 30 and the conduction electrode 40 are separately formed.

Or, the conversion electrode 30 and the conduction electrode 40 may be integrally formed. For example, the material of the conversion electrode 30 may be Ir-doped Cu, and the material of the conduction electrode 40 may be non-doped Cu. It is known that, in the Ir-doped Cu, the spin current—electric current conversion is generated with high efficiency by Ir atoms. In the case of this combination, the conversion electrode 30 and the conduction electrode 40 can be continuously formed by properly controlling the Ir-doping during the Cu film formation, which is preferable from the standpoint of the manufacturing process.

Also, the material of the conversion electrode 30 may be Fe-doped Au, and the material of the conduction electrode 40 may be non-doped Au. It is known that, in the Fe-doped Au, the spin current—electric current conversion efficiency is generated with high efficiency by Fe atoms. In the case of this combination, the conversion electrode 30 and the conduction electrode 40 can be continuously formed by properly controlling the Fe-doping during Au film formation, which is preferable from the standpoint of the manufacturing process.

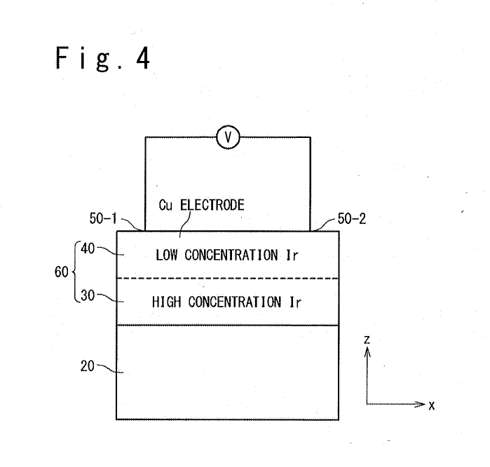

In this way, a clear boundary may not exist between the conversion electrode 30 and the conduction electrode 40. More typically, as shown in FIG. 4, non-uniformity of the doping quantity may be formed in the electrode layer 60. In FIG. 4, the electrode layer 60 includes a region (hereinafter, referred to as a “conversion region 30”) that corresponds, to the conversion electrode 30 and a region (hereinafter, referred to as a “conduction region 40”) that corresponds to the conduction electrode 40. The conversion region 30 is positioned between the magnetic layer 20 and the conduction region 40 in the z direction. For example, when a case that the material of the electrode layer 60 is the Ir-doped Cu is considered, the conversion region 30 is a high concentration Ir region, and the conduction region 40 is a low concentration Ir region. In short, the Ir-doping quantity is controlled such that Ir concentration in the conversion region 30 is higher than that in the conduction region 40. A case of the Fe-doped Au is also similar to the above. Consequently, parameters such as the resistivity and the spin current—electric current conversion efficiency are relatively high in the conversion region 30 and relatively low in the conduction region 40. Incidentally, the parameters such as the resistivity and the spin current—electric current conversion efficiency may gradually decrease with increasing distance from the magnetic layer 20.

### 2. Second Exemplary Embodiment

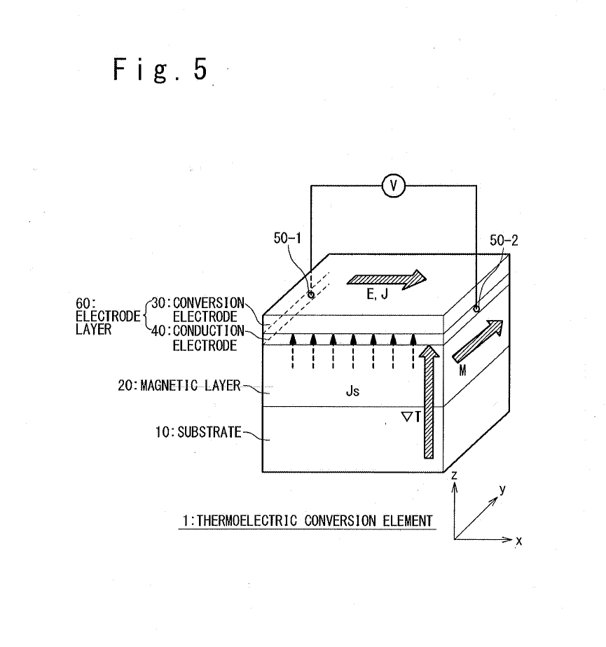

FIG. 5 is a perspective view schematically showing a configuration of a thermoelectric conversion element 1 according to the second exemplary embodiment. In the second exemplary embodiment, as compared with the first exemplary embodiment, a positional relation between the conversion electrode (conversion region) 30 and the conduction electrode (conduction region) 40 is reversed. Specifically, the conduction electrode 40 is formed on the magnetic layer 20, and the conversion electrode 30 is formed on the conduction electrode 40. In short, the conduction electrode 40 is positioned between the magnetic layer 20 and the conversion electrode 30 in the z direction. The other configurations are similar. Thus, the duplicative explanations are properly omitted.

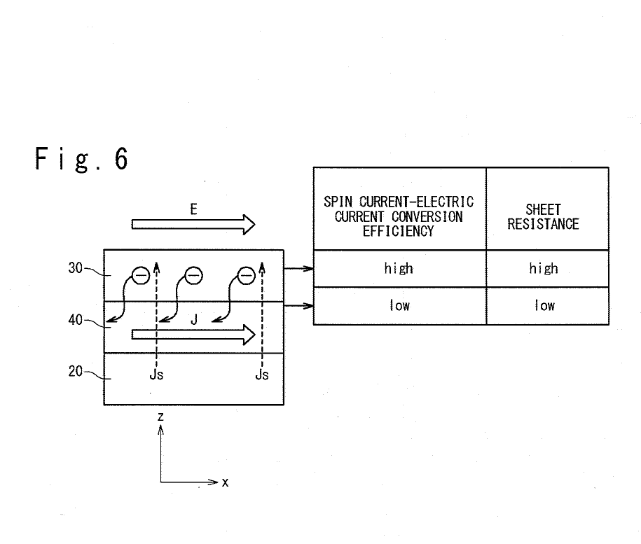

FIG. 6 shows properties of the conversion electrode 30 and the conduction electrode 40 according to the present exemplary embodiment. Similarly to the first exemplary embodiment, the sheet resistance of the conduction electrode 40 is lower than the sheet resistance of the conversion electrode 30. In addition, the spin current—electric current conversion efficiency of the conduction electrode 40 is lower than the spin current—electric current conversion efficiency of the conversion electrode 30. That is, in the conduction electrode 40 as compared with the conversion electrode 30, the electric current flows easily and the spin current—electric current conversion is difficult to occur. The material of the conversion electrode 30 and the material of the conduction electrode 40 are similar to those of the first exemplary embodiment.

In the present exemplary embodiment, the spin current Js generated in the magnetic layer 20 arrives through the conduction electrode 40 to the conversion electrode 30. Although the spin current Js is slightly relaxed in the conduction electrode 40, the spin current Js of a certain degree arrives at the conversion electrode 30. Thus, the action and effect similar to those of the first exemplary embodiment can be obtained. That is, the electric current loss caused by the reverse process in the electrode layer 60 is reduced. Incidentally, it is preferable that the film thickness of the conduction electrode 40 is set to the value less than the spin diffusion length (the spin relaxation length) of the material of the conduction electrode 40.

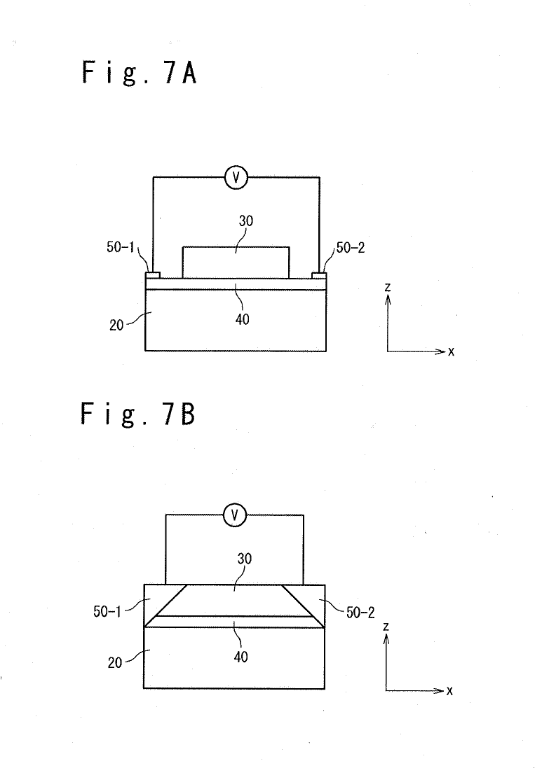

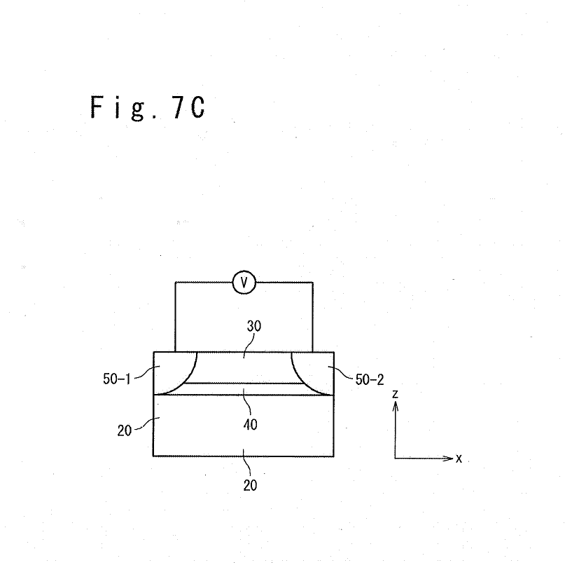

Incidentally, in the present exemplary embodiment, since the conversion electrode 30 exists on the conduction electrode 40, there is some room for better formation of the external connection terminals 50-1 and 50-2. For example, as shown in FIG. 7A, the conduction electrode 40 is formed larger than the conversion electrode 30, and the external connection terminals 50-1 and 50-2 are formed in contact with the exposure portion on the top surface of the conduction electrode 40. Or, as shown in FIG. 7B, the end portions of the lamination structure between the conduction electrode 40 and the conversion electrode 30 are removed in oblique directions, and the external connection terminals 50-1 and 50-2 may be formed in the removed portions. Or, similarly as shown in FIG. 7C, the material of the conduction electrode 40 and the material of the conversion electrode 30 may be partially mixed by using, for example, a heating means and so on, and the external connection terminals 50-1 and 50-2 may be consequently formed. Or, similarly as shown in FIG. 7C, the lamination structure between the conduction electrode 40 and the conversion electrode 30 may be formed to have partially low resistance portions by using a means of the diffusion of atoms and molecules or a means of the injection of atoms and molecules and soon, and the external connection terminals 50-1 and 50-2 may be the low resistance portions. The cases of FIG. 7A to FIG. 7C are preferable that the contact areas between the conduction electrode 40 and the external connection terminals 50-1 and 50-2 are increased as compared with the case of FIG. 5.

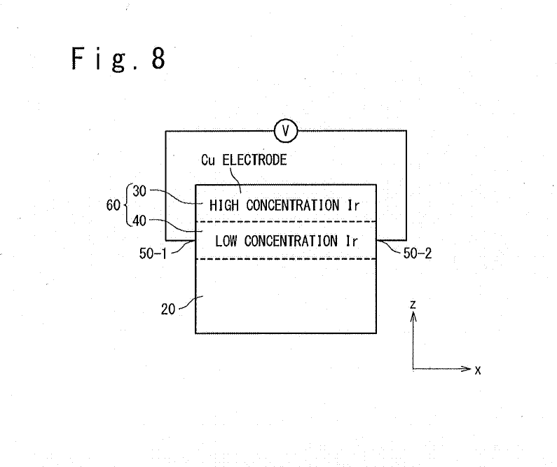

Also, similarly to the first exemplary embodiment, the clear boundary may not exist between the conversion electrode 30 and the conduction electrode 40. As shown in FIG. 8, the electrode layer 60 may include the conversion region 30 and the conduction region 40. The conduction region 40 is positioned between the magnetic layer 20 and the conversion region 30 in the z direction. For example, when the case that the material of the electrode layer 60 is the Ir-doped Cu is considered, the conversion region 30 is the high concentration Ir region and the conduction region 40 is the low concentration Ir region. In short, the Ir-doping quantity is controlled such that the Ir concentration of the conversion region 30 is higher than that of the conduction region 40. The case of the Fe-doped Au is also similar to the above. Consequently, the parameters such as the resistivity and the spin current—electric current conversion efficiency are relatively high in the conversion region 30 and relatively low in the conduction region 40. Incidentally, the parameters such as the resistivity and the spin current—electric current conversion efficiency may gradually increase with increasing distance from the magnetic layer 20.

### 3. Third Exemplary Embodiment

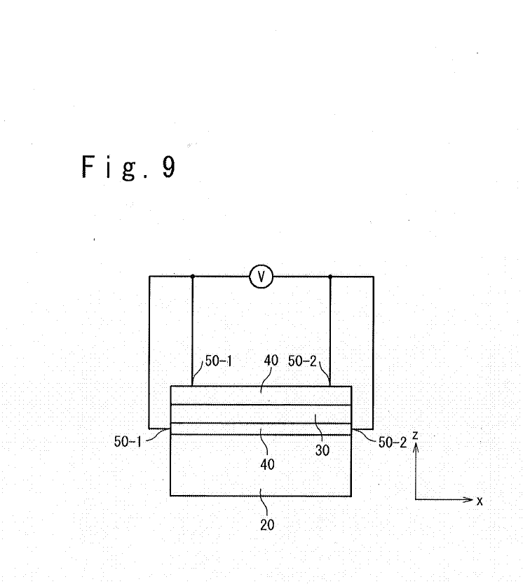

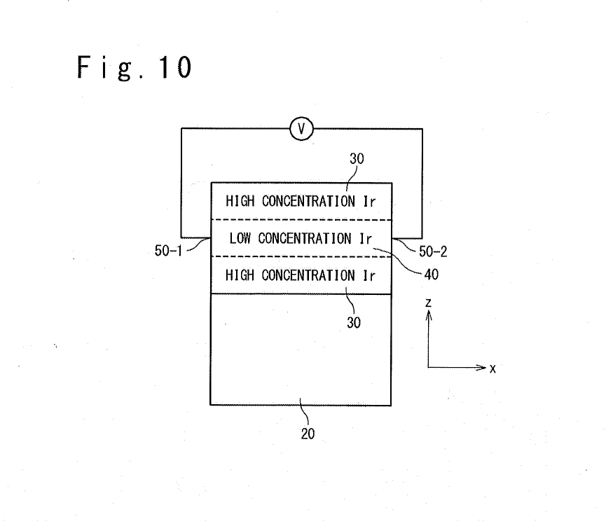

The parameters such as the resistivity and the spin current—electric current conversion efficiency of the electrode layer 60 may not always monotonously increase or decrease with increasing distance from the magnetic layer 20. For example, in the configuration shown in FIG. 9, the conduction electrode 40 is formed on the magnetic layer 20, the conversion electrode 30 is formed on the conduction electrode 40 and a different conduction electrode 40 is further formed on the conversion electrode 30. As another example, in the configuration shown in FIG. 10, the conversion region 30 is formed on the magnetic layer 20, the conduction region 40 is formed on the conversion region 30, and a different conversion region 30 is further formed on the conduction region 40. Even by those configurations, the action and effect similar to those of the already-described exemplary embodiments can be obtained. That is, the loss of the electric current caused by the reverse process in the electrode layer 60 can be reduced.

### 4. Fourth Exemplary Embodiment

In the already-described exemplary embodiments, the conversion electrode (conversion region) 30 and the conduction electrode (conduction region) 40 are distributed in the z direction in the electrode layer 60. However, those positional relations are not limited to it. The fourth exemplary embodiment will be described about a case that the conversion electrode (conversion region) 30 and the conduction electrode (conduction region) 40 are distributed in the in-plane direction of the electrode layer 60.

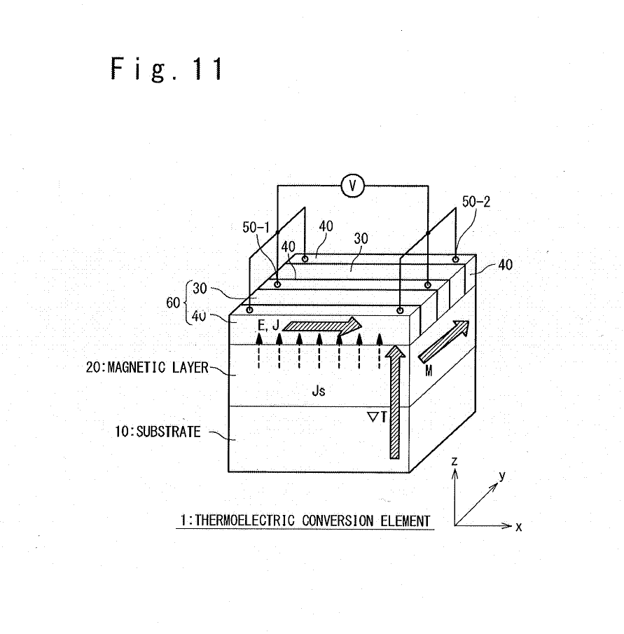

FIG. 11 is a perspective view schematically showing a configuration of the thermoelectric conversion element according to the fourth exemplary embodiment. The electrode layer 60 includes the conversion electrodes 30 and the conduction electrodes 40. Both of the conversion electrodes 30 and the conduction electrodes 40 are formed on the magnetic layer 20 and distributed in the in-plane direction. Also, the external connection terminals 50-1 and 50-2 are formed in contact with the conduction electrode 40.

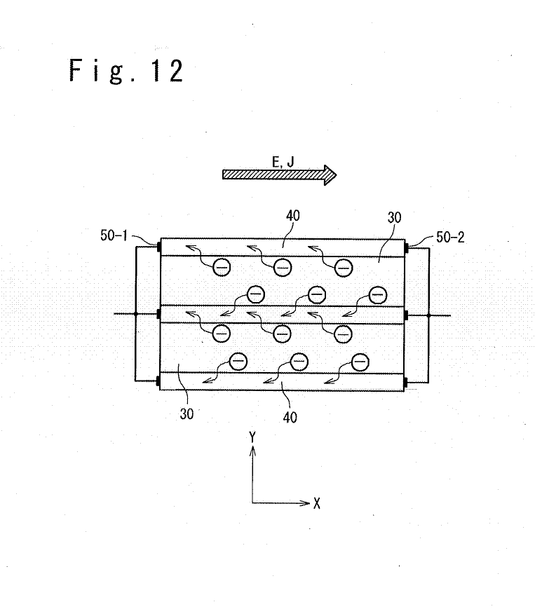

FIG. 12 shows a configuration example (within the xy plane) of the electrode layer 60 in the present exemplary embodiment. In the example shown in FIG. 12, the conduction electrodes 40 are formed to extend in an electromotive force direction (x direction) and the conversion electrodes 30 are formed to be sandwiched between the conduction electrodes 40. Also, the external connection terminals 50-1 and 50-2 are arranged at both ends of each of the conduction electrodes 40, respectively.

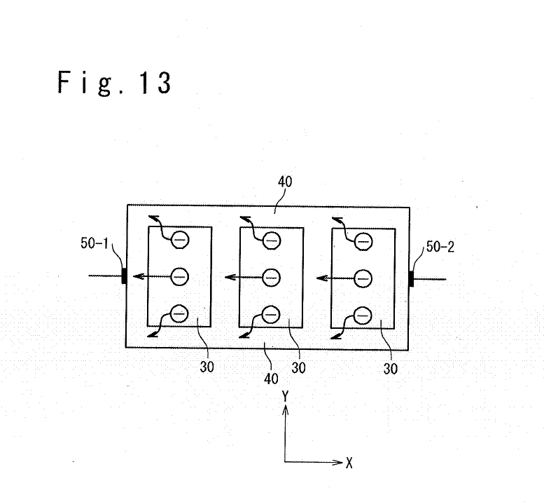

FIG. 13 shows another configuration example (within the xy plane) of the electrode layer 60 in the present exemplary embodiment. In the example shown in FIG. 13, the conduction electrode 40 is formed in “a shape of ladders”, and the conversion electrodes 30 are formed in gap in the conduction electrode 40. Also, the external connection terminals 50-1 and 50-2 are arranged at both of the ends of the conduction electrode 40 in the x direction.

In any case, in the conversion electrode 30, the inverse spin-Hall effect is greatly developed, and the spin current Js is converted into the electric current with high efficiency. Most of the electric current generated in the conversion electrode 30 is transmitted to the conduction electrode 40 whose sheet resistance is lower than that of the conversion electrode 30. In the conduction electrode 40, the spin-Hall effect is not almost developed and most of the electric current is not converted into the spin current. That is, the effects similar to those of the already-described exemplary embodiments can be obtained.

Incidentally, as shown in FIG. 13, in a case that the conduction electrode 40 has a portion extending in a direction which intersects the electromotive force direction (x direction), electrons are easily transmitted into the portion from the conversion electrode 30, which is consequently preferable.

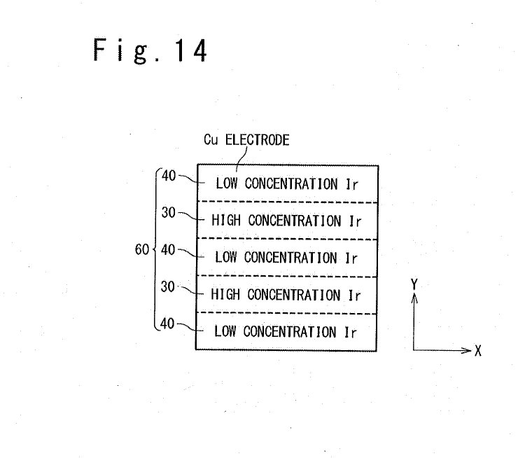

Also, similarly to the already-described exemplary embodiments, the clear boundary may not exist between the conversion electrode 30 and the conduction electrode 40. As shown in FIG. 14, the electrode layer 60 may include the conversion regions 30 and the conduction regions 40. The conversion regions 30 and the conduction regions 40 are distributed in the in-plane direction of the electrode layer 60. For example, when the case that the material of the electrode layer 60 is the Ir-doped Cu is considered, the conversion region 30 is the high concentration Ir region, and the conduction region 40 is the low concentration Ir region. In short, the Ir-doping quantity is controlled such that the Ir concentration of the conversion region 30 is higher than that of the conduction region 40. The case of the Fe-doped Au is also similar to the above. Consequently, the parameters such as the resistivity and the spin current—electric current conversion efficiency are relatively high in the conversion region 30 and relatively low in the conduction region 40.

### 5. Fifth Exemplary Embodiment

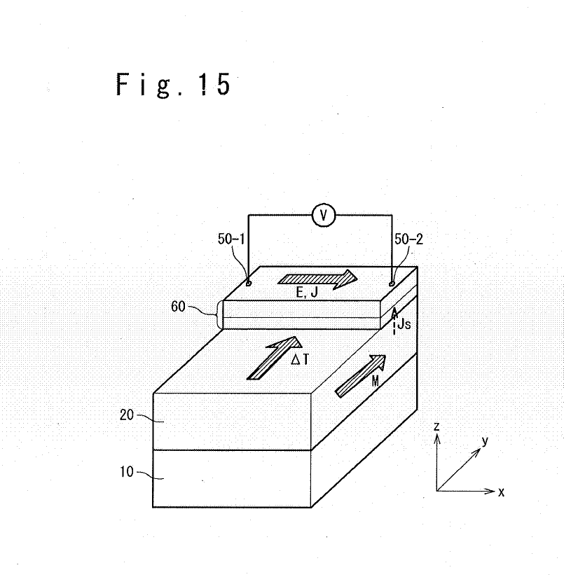

FIG. 15 is a perspective view schematically showing a configuration of the thermoelectric conversion element 1 according to the fifth exemplary embodiment. In the fifth exemplary embodiment, the temperature gradient ∇T is given to the in-plane direction (y direction) and not the lamination direction (x direction). In detail, the magnetic layer 20 is formed to extend in the y direction. The electrode layer 60 is formed on a part of the magnetic layer 20. When the temperature gradient ∇T in the y direction is applied, the spin current Js along the y direction is generated in the magnetic layer 20. However, on the interface between the magnetic layer 20 and the electrode layer 60, the direction of the spin current Js is changed to the z direction. Thus, similarly to the case of the above-mentioned exemplary embodiments, the electromotive force is generated in the x direction. Incidentally, the configuration of the electrode layer 60 may be any of the already-described exemplary embodiments.

### 6. CONCLUSION

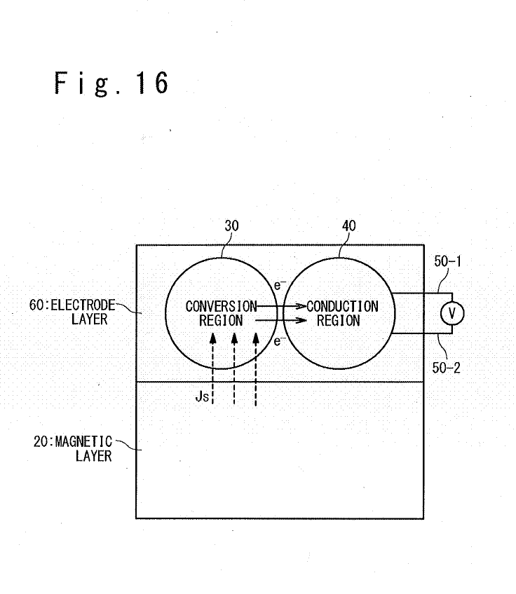

FIG. 16 summarily shows a configuration of the thermoelectric conversion element 1 according to the exemplary embodiment of the present invention. The electrode layer 60 formed on the magnetic layer 20 includes the conversion region 30 and the conduction region 40. The parameters such as the resistivity and the spin current—electric current conversion efficiency of the conversion region 30 are high and those of the conduction region 40 are low. In order to attain the foregoing parameter difference, for example, the conversion region 30 and the conduction region 40 are configured by the electrode films (the conversion electrode 30 and the conduction electrode 40) that differ from each other (refer to FIG. 2, FIG. 5, FIG. 9 and FIG. 11). Or, on the basis of the non-uniformity of the doping concentration in the electrode layer 60, the foregoing parameter difference may be attained (refer to FIG. 4, FIG. 8, FIG. 10 and FIG. 14).

Also, the positional relation between the conversion region 30 and the conduction region 40 is variously considered. For example, as shown in the first exemplary embodiment, the conversion region 30 may be positioned between the magnetic layer 20 and the conduction region 40 in the z direction. Or, as shown in the second exemplary embodiment, the conduction region 40 may be positioned between the magnetic layer 20 and the conversion region 30 in the z direction. Or, as shown in the third exemplary embodiment, the conversion region 30 and the conduction region 40 may be distributed in the in-plane direction of the electrode layer 60.

The functions of the thus-configured thermoelectric conversion element 1 are as follows. The spin current Js generated in the magnetic layer 20 flows through the electrode layer 60. In the conversion region 30 of the electrode layer 60, the inverse spin-Hall effect is greatly developed, and the spin current Js is converted into the electric current with high efficiency. Most of the electric current generated in the conversion region 30 is transmitted to the conduction region 40 whose sheet resistance is lower than that of the conversion region 30.

In the conduction region 40, the spin-Hall effect is not almost developed, and most of the electric current is not converted into the spin current. That is, a part of the electric current, which is converted from the spin current Js by the inverse spin-Hall effect, is almost prevented from being returned to the spin current by the spin-Hall effect. Thus, the loss of the electric current in the electrode layer 60 can be reduced.

Also, the electric power can be extracted from the external connection terminals 50-1 and 50-2 that are formed in contact with the conduction region 40 of the electrode layer 60.

The manufacturing method will be described below. At first, the magnetic layer 20 is formed. After that, the electrode layer 60 that includes the conversion region 30 and the conduction region 40 is formed on the magnetic layer 20. Here, the parameters such as the resistivity and the spin current—electric current conversion efficiency of the conversion region 30 are high, and those of the conduction region 40 are low. In order to attain the foregoing parameter difference, for example, the conversion region 30 and the conduction region 40 are configured by the electrode films (the conversion electrode 30 and the conduction electrode 40) that differ from each other (refer to FIG. 2, FIG. 5, FIG. 9 and FIG. 11). Or, on the basis of the non-uniformity of the doping concentration in the electrode layer 60, the foregoing parameter difference may be attained (refer to FIG. 4, FIG. 8, FIG. 10 and FIG. 14).

As mentioned above, the exemplary embodiments of the present invention have been described with reference to the attached drawings. However, the present invention is not limited to the above-mentioned exemplary embodiments and it will be understood by those of ordinary skill in the art that various changes may be made therein without departing from the spirit and scope of the present invention.

The whole or part of the exemplary embodiments disclosed above can be described as, but not limited to, the following supplementary notes.

### (Supplementary Note 1)

A thermoelectric conversion element including:

a magnetic layer; and

an electrode layer formed on the magnetic layer,

wherein the electrode layer includes:
a first region, and
a second region having lower spin current—electric current conversion efficiency and resistivity than those of the first region.

### (Supplementary Note 2)

The thermoelectric conversion element described in the supplementary note 1, further including an external connection terminal formed in contact with the second region of the electrode layer.

### (Supplementary Note 3)

The thermoelectric conversion element described in the supplementary note 1 or 2, wherein, when a lamination direction between the magnetic layer and the electrode layer is a first direction, the first region and the second region are distributed in the first direction.

### (Supplementary Note 4)

The thermoelectric conversion element described in the supplementary note 3, wherein the first region is positioned between the magnetic layer and the second region, in the first direction.

### (Supplementary Note 5)

The thermoelectric conversion element described in the supplementary note 3, wherein the second region is positioned between the magnetic layer and the first region, in the first direction.

### (Supplementary Note 6)

The thermoelectric conversion element described in the supplementary note 1 or 2, wherein the first region and the second region are distributed in an in-plane direction of the electrode layer.

### (Supplementary Note 7)

The thermoelectric conversion element described in anyone of the supplementary notes 1 to 6, wherein the first region is a first electrode film,

wherein the second region is a second electrode film made of material different from the first electrode film, and

wherein a spin current—an electric current conversion efficiency and a sheet resistance of the second electrode film is lower than those of the first electrode film.

### (Supplementary Note 8)

The thermoelectric conversion element described in the supplementary note 7, wherein material of the first electrode film includes Au, Pt, Pd or Ir, or other metal having an f-orbit, or alloy including any of them.

### (Supplementary Note 9)

The thermoelectric conversion element described in any one of the supplementary notes 1 to 6, wherein material of the electrode layer includes Ir-doped Cu, and

wherein an Ir concentration of the first region is higher than that of the second region.

### (Supplementary Note 10)

The thermoelectric conversion element described in any one of the supplementary notes 1 to 6, wherein material of the electrode layer includes Fe-doped Cu, and

wherein a Fe concentration of the first region is higher than that of the second region.

### (Supplementary Note 11)

A method of manufacturing a thermoelectric conversion element including:
forming a magnetic layer; and
forming an electrode layer including a first region and a second region having lower spin current—electric current conversion efficiency and resistivity than those of the first region, on the magnetic layer.

This application is based upon and claims the benefit of priority from Japanese patent application No. 2011-210545 filed on Sep. 27, 2011 and Japanese patent application No. 2012-044148 filed on Feb. 29, 2012, the disclosures of which are incorporated herein in their entireties by reference.

1. A thermoelectric conversion element comprising:
a magnetic layer; and
an electrode layer formed on said magnetic layer,
wherein said electrode layer includes:
a first region, and
a second region having lower spin current—electric current conversion efficiency and resistivity than those of said first region.

2. The thermoelectric conversion element according to claim 1, further comprising:
an external connection terminal formed in contact with said second region of said electrode layer.

3. The thermoelectric conversion element according to 1, wherein, when a lamination direction between said magnetic layer and said electrode layer is a first direction, said first region and said second region are distributed in said first direction.

4. The thermoelectric conversion element according to claim 3, wherein said first region is positioned between said magnetic layer and said second region, in said first direction.

5. The thermoelectric conversion element according to claim 3, wherein said second region is positioned between said magnetic layer and said first region, in said first direction.

6. The thermoelectric conversion element according to claim 1, wherein said first region and said second region are distributed in an in-plane direction of said electrode layer.

7. The thermoelectric conversion element according to claim 1, wherein said first region is a first electrode film,
wherein said second region is a second electrode film made of material different from said first electrode film, and
wherein a spin current—an electric current conversion efficiency and a sheet resistance of said second electrode film is lower than those of said first electrode film.

8. The thermoelectric conversion element according to claim 7, wherein material of said first electrode film includes Au, Pt, Pd or Ir, or other metal having an f-orbit, or alloy including any of them.

9. The thermoelectric conversion element according to claim 1, wherein material of said electrode layer includes Ir-doped Cu, and
wherein an Ir concentration of said first region is higher than that of said second region.

10. The thermoelectric conversion element according to claim 1, wherein material of said electrode layer includes Fe-doped Cu, and
wherein a Fe concentration of said first region is higher than that of said second region.

11. A method of manufacturing a thermoelectric conversion element comprising:
forming a magnetic layer; and
forming an electrode layer including a first region and a second region having lower spin current—electric current conversion efficiency and resistivity than those of said first region, on said magnetic layer.
